(19) United States
(12) Patent Application Publication
(10) Pub. No.: US 2013/0069074 A1
(43) Pub. Date: Mar. 21, 2013

(54) POWER DEVICE AND METHOD OF MANUFACTURING THE SAME

(71) Applicants: Jae-won LEE, Seoul (KR); Su-hee CHAE, Suwon-si (KR); Jun-youn KIM, Hwaseong-si (KR); In-jun HWANG, Hwaseong-si (KR); Hyo-ji CHOI, Seoul (KR)

(72) Inventors: Jae-won LEE, Seoul (KR); Su-hee CHAE, Suwon-si (KR); Jun-youn KIM, Hwaseong-si (KR); In-jun HWANG, Hwaseong-si (KR); Hyo-ji CHOI, Seoul (KR)

(73) Assignee: SAMSUNG ELECTRONICS CO., LTD., Suwon-si (KR)

(21) Appl. No.: 13/610,025

(22) Filed: Sep. 11, 2012

(30) Foreign Application Priority Data
Sep. 21, 2011 (KR) 10-2011-0095406

(51) Int. Cl. H01L 29/778; H01L 21/335; H01L 29/205

(52) U.S. Cl. 257/76; 257/194; 438/172; 257/E29.246; 257/E29.091; 257/E21.407

(57) ABSTRACT

According to an example embodiment, a power device includes a substrate, a nitride-containing stack on the substrate, and an electric field dispersion unit. Source, drain, and gate electrodes are on the nitride-containing stack. The nitride-containing stack includes a first region that is configured to generate a larger electric field than that of a second region of the nitride-containing stack. The electric field dispersion unit may be between the substrate and the first region of the nitride-containing stack.

### CROSS-REFERENCE TO RELATED APPLICATIONS

This application claims priority under 35 U.S.C. §119 to Korean Patent Application No. 10-2011-0095406, filed on Sep. 21, 2011, in the Korean Intellectual Property Office, the disclosure of which is incorporated herein in its entirety by reference.

### BACKGROUND

1. Field

Some example embodiments relate to power devices having improved withstanding voltage and heat radiation characteristics, and/or methods of manufacturing the power devices.

2. Description of the Related Art

Nitride semiconductor devices may be used as, for example, power devices used to control electric power. A nitride semiconductor device may be used by growing a nitride layer on a substrate formed of, for example, sapphire, silicon carbide, or silicon. However, since a sapphire substrate has a large thermal resistance, the sapphire substrate limits heat dissipation through the substrate of the device. In addition, although a silicon carbide substrate has a lower thermal resistance and therefore better heat dissipation properties compared to a sapphire substrate, forming a large-size silicon carbide substrate is more difficult than forming a large-size sapphire substrate. A silicon substrate may be used as a large-size substrate.

One example of a power device is a high electron mobility transistor (HEMT). The HEMT includes a two-dimensional electron gas (2DEG) used as a carrier in a channel layer. Since the 2DEG is used as a carrier, the electron mobility of the HEMT is higher than that of other general transistors.

The HEMT includes a compound semiconductor having a wide band gap. Therefore, a breakdown voltage of the HEMT may be greater than that of other general transistors. The breakdown voltage of the HEMT may increase in proportion to a thickness of a compound semiconductor layer including the 2DEG, for example, a GaN layer.

However, a critical field of a silicon substrate in the HEMT is lower than that of the GaN layer. That is, the breakdown voltage of the silicon substrate included in the HEMT is lower than the breakdown voltage of the GaN layer formed on the silicon substrate. The breakdown voltage of the HEMT may be lowered due to the silicon substrate. Therefore, the breakdown voltage may be increased by removing the silicon substrate; however, heat dissipation efficiency may be degraded when the silicon substrate is removed.

### SUMMARY

Some example embodiments relate to power devices having improved withstanding voltage characteristics and heat dissipation characteristics.

Other example embodiments relate to methods of manufacturing power devices.

Additional aspects will be set forth in part in the description which follows and, in part, will be apparent from the description, or may be learned by practice of example embodiments.

According to an example embodiment, a power device includes: a substrate; a nitride-containing stack on the substrate; a source electrode, a drain electrode, and a gate electrode on the nitride-containing stack; and an electric field dispersion unit. The nitride-containing stack includes a first region that is configured to generate a larger electric field than that of a second region of the nitride-containing stack. The electric field dispersion unit is between the substrate and the first region of the nitride-containing stack.

The electric field dispersion unit may include a dielectric material.

The electric field dispersion unit may be on a part of a bottom surface of the nitride-containing stack. The electric dispersion unit may be located in a region of the nitride-containing stack that is not under the source electrode.

The dielectric material may include one of SiO₂, SiN, AlN, or Al₂O₃.

The electric field dispersion unit may be formed on an entire region or a part of the bottom surface of the nitride-containing stack by ion implantation.

The ion implantation may be performed using a source material that forms a deep trap in the bottom surface of the nitride-containing stack.

The ion implantation may be performed using at least one source material selected from the group consisting of N, O, He, H, F, C, and Fe.

The ion implantation may be performed to a depth of 10 nm or greater.

The electric field dispersion unit may have a high resistive property.

The electric field dispersion unit may be under a part of the drain electrode.

The electric field dispersion unit may be under a part of an upper surface of the nitride-containing stack. The part of the upper surface of the nitride-containing stack may be between the gate electrode and the drain electrode.

The power device may be a high electron mobility transistor.

The device may further include at least one bonding metal layer between the nitride-containing stack and the substrate.

The at least one bonding metal layer may include a material including at least one of Cu, Au, and Sn.

The substrate may include a material having high thermal conductivity.

The substrate may include one of Si, Al, Cu, SiC, GaN, AlN, and a direct bonded copper (DBC).

According to another example embodiment, a power device includes: a substrate; a buffer layer on the substrate; a GaN channel layer on the buffer layer; a channel supply layer on the channel layer; a source electrode, a drain electrode, and a gate electrode on the channel supply layer; and an electric field dispersion unit on one of a portion region of the buffer layer and at least a portion region of a bottom surface of the buffer layer. The electric field dispersion unit may be configured to disperse an electric field.

The buffer layer may be a nitride material that includes at least one of B, Al, Ga, In, and combinations thereof.

The channel supply layer may be a nitride material that includes at least one of B, Al, Ga, and In, and combinations thereof.

According to an example embodiment, a method of manufacturing a power device includes: stacking a buffer layer on a first substrate; stacking at least one nitride semiconductor layer on the buffer layer; forming a source electrode, a gate electrode, and a drain electrode on the at least one nitride semiconductor layer; removing the first substrate; forming an electric field dispersion unit on at least a region of a bottom surface of the buffer layer; and forming a second substrate on the buffer layer and the electric field dispersion unit.

The forming of the electric field dispersion unit may include: patterning a part of the buffer layer; and stacking a dielectric material in the patterned portion.

The forming of the electric field dispersion unit may include: forming at least one bonding metal layer on the buffer layer; patterning a part of the bonding metal layer; stacking a dielectric material in the patterned part of the at least one bonding metal layer; patterning the second substrate; and bonding the second substrate to the at least one bonding metal layer so that the dielectric material and the patterned part of the second substrate are bonded to each other.

The forming of the electric field dispersion unit may include performing an ion implantation on a part or an entire part of the buffer layer.

### BRIEF DESCRIPTION OF THE DRAWINGS

The foregoing and other features of example embodiments will become apparent and more readily appreciated from the following description of non-limiting embodiments, as illustrated in the accompanying drawings in which like reference characters refer to the same parts throughout the different views. The drawings are not necessarily to scale, emphasis instead being placed upon illustrating the principles of some example embodiments. In the drawings:

FIG. 1 is a schematic cross-sectional view of a power device according to a first example embodiment;

FIG. 2 is a schematic cross-sectional view of a power device according to a second example embodiment;

FIG. 3 is a schematic cross-sectional view of a power device according to a third example embodiment;

FIG. 4 is a schematic cross-sectional view of a power device according to a fourth example embodiment;

FIG. 5 is a schematic cross-sectional view of a power device according to a fifth example embodiment;

FIGS. 6A through 6H are cross-sectional views illustrating a method of manufacturing a power device, according to an example embodiment;

FIGS. 7A through 7G are cross-sectional views illustrating a method of manufacturing a power device, according to another example embodiment; and

FIGS. 8A through 8G are cross-sectional views illustrating a method of manufacturing a power device, according to a different example embodiment.

FIGS. 9A to 9D are schematic cross-sectional views of power devices according to some example embodiments.

### DETAILED DESCRIPTION

Inventive concepts will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”). It will be understood that when an element or layer is referred to as being “on” another element or layer, the element or layer can be directly on another element or layer or intervening elements or layers.

As used herein, the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

FIG. 1 is a schematic cross-sectional view of a power device 1 according to a first example embodiment. Referring to FIG. 1, a nitride-containing stack 20 may be disposed on a substrate 10. The substrate 10 may be formed of a material having a high thermal conductivity. The substrate 10 may be formed of, for example, Si, Al, Cu, SiC, GaN, AlN, or direct bonded copper (DBC). The nitride-containing stack 20 may include a plurality of nitride layers. A nitride layer may be formed of AlₓIn_{y}Ga_{1-x-y}N (0≦x, y≦1, x+y<1), for example. The plurality of nitride layers may be formed of a material including, for example, at least one of GaN, InN, AlN, AlGaN, AlInN, InGaN, and AlInGaN.

A source electrode 51, a drain electrode D1, and a gate electrode G1 may be disposed on the nitride-containing stack 20. The source electrode 51 and the drain electrode D1 are disposed on the nitride-containing stack 20 to be separated from each other, and the gate electrode G1 may be disposed between the source and the drain electrodes 51 and D1 to be separated respectively from the source and the drain electrodes 51 and D1. The gate electrode G1 may be closer to the source electrode 51 than the drain electrode D1. The source electrode 51, drain electrode D1, and gate electrode G1, may be formed of metals and/or metal nitrides, but example embodiments are not limited thereto.

An electric field dispersion unit 25 may be disposed on a region between the substrate 10 and the nitride-containing stack 20, which includes a region where a relatively larger electric field is generated than any other regions. The region between the substrate 10 and the nitride-containing stack 20 may include a region from a rear surface of the nitride-containing stack 20 facing the substrate 10 to a portion of a layer in the nitride-containing stack 20, or from a rear surface of the nitride-containing stack 20 facing the substrate 10 to the substrate 10.

In FIG. 1, the electric field dispersion unit 25 is disposed between the rear surface of the nitride-containing stack 20 and a portion of a layer of the nitride-containing stack 20. The electric field dispersion unit 25 may be formed on an entire rear surface of the nitride-containing stack 20 or a part of the rear surface of the nitride-containing stack 20. For example, the electric field dispersion unit 25 may be disposed on a region that includes at least a part of a lower portion of the drain electrode D1. Otherwise, the electric field dispersion unit 25 may be disposed on the rear surface of the nitride-containing stack 20, for example, a lower region between the gate electrode G1 and the drain electrode D1.

There may be a region where the electric field is relatively largely concentrated than any other regions in the nitride-containing stack 20 where breakdown may largely occur. For example, the electric field may concentrate on the lower region between the gate electrode G1 and the drain electrode D1 in the nitride-containing stack 20, and thus, may be weak against the breakdown at a high voltage. Here, the electric field dispersion unit 25 is disposed at the lower region between the gate electrode G1 and the drain electrode D1 on the rear surface of the nitride-containing stack 20 so as to disperse the concentrated electric field, and thus, a withstanding voltage characteristic may be improved. In addition, heat generated from the nitride-containing stack 20 may be dissipated through the substrate 20, thereby reducing degradation of electric current characteristics, which may be caused by the heat.

The electric field dispersion unit 25 may be formed of a material having a high resistive property in order to improve the withstanding voltage characteristic. The electric field dispersion unit 25 may be formed of, for example, a dielectric material. The dielectric material may be SiO₂, SiN, AlN, or Al₂O₃. Otherwise, the electric field dispersion unit 25 may be formed by an ion implantation process. The ion implantation may be performed using a source material that may form a deep trap in the rear surface of the nitride-containing stack 20. The ion implantation may be performed using at least one source material selected from the group consisting of N, O, He, H, F, C, and Fe. The ion implantation may be performed to a depth of 10 nm or greater.

At least one bonding metal layer may be further disposed between the substrate 10 and the nitride-containing stack 20. The at least one bonding metal layer may include a first bonding metal layer 15 and a second bonding metal layer 17. The first and second bonding metal layers 15 and 17 may be formed of a material including at least one of Cu, Au, and Sn, for example. The substrate 10 and the nitride-containing stack 20 may be bonded to each other via the first and second bonding metal layers 15 and 17.

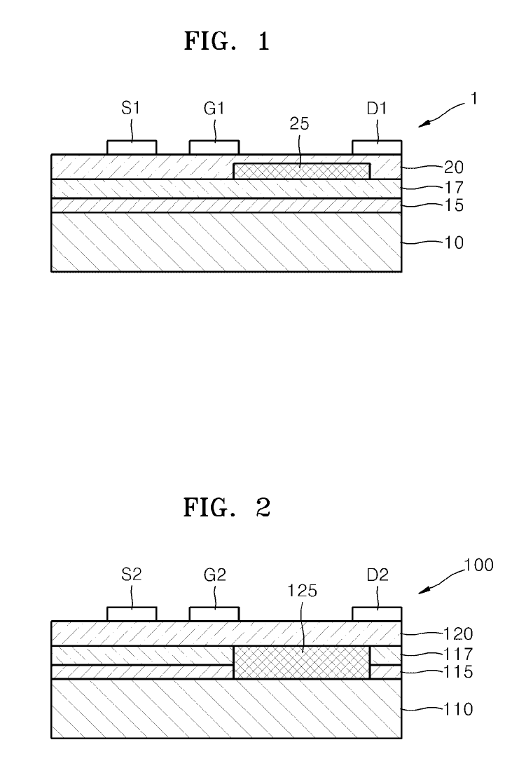

FIG. 2 is a schematic cross-sectional view of a power device 100 according to a second example embodiment. Referring to FIG. 2, at least one bonding metal layer is disposed on a substrate 110, and a nitride-containing stack 120 may be disposed on the at least one bonding metal layer. The substrate 110 may be formed of a material having a high thermal conductivity. The substrate 110 may be formed of, for example, Si, Al, Cu, SiC, GaN, AlN, or DBC. In addition, a source electrode S2, a drain electrode D2, and a gate electrode G2 may be disposed on the nitride-containing stack 120.

The at least one bonding metal layer may include a first bonding metal layer 115 and a second bonding metal layer 117. An electric field dispersion unit 125 may be disposed on a region between the substrate 110 and the nitride-containing stack 120, which includes a region where a relatively larger electric field is generated than any other regions. The electric field dispersion unit 125 may be disposed between the substrate 110 and a rear surface of the nitride-containing stack 120 facing the substrate 110. For example, the electric field dispersion unit 125 may be disposed on some regions of the first and second bonding metal layers 115 and 117. The electric field dispersion unit 125 may be disposed on the first bonding metal layer 115 and a region of the second bonding metal layer 117, which includes at least a part of the lower portion under the drain electrode D2. Otherwise, the electric field dispersion unit 125 may be formed on, for example, regions of the first and second bonding metal layers 115 and 117, which may include at least a lower portion between the gate electrode G2 and the drain electrode D2. That is, the electric field dispersion unit 125 may be disposed on the lower portion between the gate electrode G2 and the drain electrode D2, or to a larger region including the lower portion between the gate electrode G2 and the drain electrode D2.

The electric field dispersion unit 125 may be formed of a material having a high resistive property in order to improve the withstanding voltage characteristic. The electric field dispersion unit 125 may be formed of, for example, a dielectric material, which may include at least one of SiO₂, SiN, AlN, or Al₂O₃.

The withstanding voltage characteristic may be improved by forming the electric field dispersion unit 125 on the lower portion between the gate electrode G2 and the drain electrode D2 in order to disperse the concentrated electric field. In addition, degradation of electric current characteristics may be reduced by dissipating heat generated from the nitride-containing stack 120 through the substrate 110.

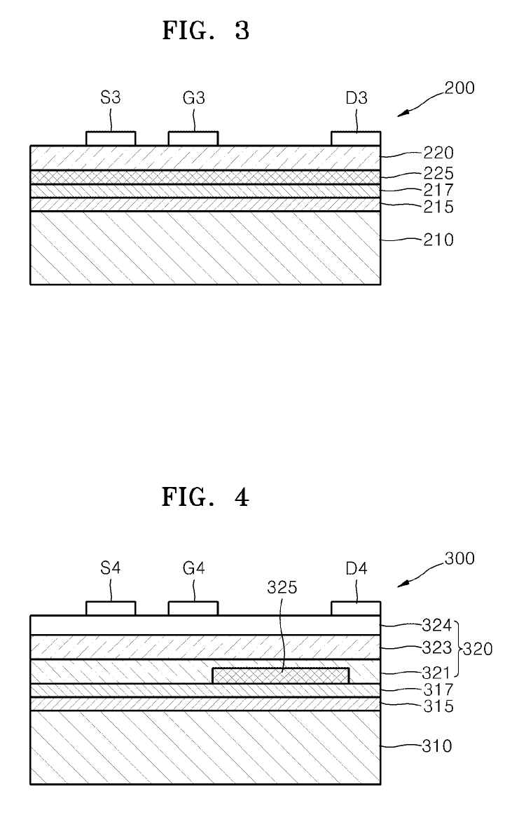

FIG. 3 is a cross-sectional view of a power device 200 according to a third example embodiment. Referring to FIG. 3, a nitride-containing stack 220 may be disposed on a substrate 210. A source electrode S3 and a drain electrode D3 are disposed on the nitride-containing stack 220 to be separated from each other, and a gate electrode G3 may be disposed between the source and the drain electrodes S3 and D3 to be separated from both of the source and drain electrodes S3 and D3.

An electric field dispersion unit 225 may be disposed between the substrate 210 and the nitride-containing stack 220. The electric field dispersion unit 225 may be formed on an entire portion between the substrate 210 and the nitride-containing stack 220. The electric field dispersion unit 225 may be formed by, for example, an ion implantation process. The electric field dispersion unit 225 may be formed on the entire portion between the substrate 210 and the nitride-containing stack 220 by a blank implantation process. Thus, the electric field may be dispersed on the region where the electric field is locally concentrated, and at the same time, flow of heat from the nitride-containing stack 220 may not interfere with other regions. The ion implantation may be performed using at least one source material selected from the group consisting of N, O, He, H, F, C, and Fe.

First and second bonding metal layers 215 and 217 may be further disposed between the substrate 210 and the nitride-containing stack 220. The substrate, the nitride-containing stack 220, and the first and second bonding metal layers 215 and 217 are substantially the same as those described with reference to FIG. 1, and thus, detailed descriptions thereof are not provided here.

FIG. 4 is a cross-sectional view of a power device 300 according to a fourth example embodiment. Referring to FIG. 4, a nitride-containing stack 320 is disposed on a substrate 310, and an electric field dispersion unit 325 may be disposed from a rear surface of the nitride-containing stack 320 facing the substrate 310 to a portion of a layer of the nitride-containing stack 320. The substrate 310 may be formed of a material having a high thermal conductivity. The substrate 310 may be formed of, for example, Si, Al, Cu, SiC, GaN, AlN, or DBC. The nitride-containing stack 320 may include a plurality of nitride layers.

The nitride-containing stack 320 may include, for example, a buffer layer 321, a channel layer 323, and a channel supply layer 324. The buffer layer 321 may be formed to reduce a dislocation density caused by difference between lattice constants of the substrate 310 on which the nitride-containing stack 320 is grown and the channel layer 323, and to prevent cracks from generating due to difference between thermal expansion coefficients of the substrate 310 and the channel layer 323. The buffer layer 321 may be formed to have a stacked structure including a nitride including at least one of the group consisting of Al, Ga, and In, and a compound thereof. Otherwise, the buffer layer 321 may formed of a material including one selected from the group consisting of AlₓIn_{y}Ga_{1-x-y}N (0≦x, y≦1, x+y<1), step grade AlₓIn_{y}Ga_{1-x-y}N (0≦x, y≦1, x+y≦1), and Alₓ₁In_{y1}Ga_{1-x1-y1}N/Alₓ₂In_{y2}Ga_{1-x2-y2}N (0≦x1, x2, y1, y2≦1, x1≠x2 or y1≠y2, x1+y1≦1, x2+y2≦1) superlattice. The buffer layer 321 may include a plurality of layers, for example, may be formed of GaN, AlN, and/or AlGaN. If the buffer layer 321 includes a plurality of layers, one of the plurality of layers may function as a nuclear growth layer.

The channel layer 323 may be formed as a nitride-containing stack. For example, the channel layer 323 may be a compound semiconductor layer such as a GaN layer. The channel layer 323 may be an undoped GaN layer, if desired, the GaN layer may be doped with desired (or alternatively predetermined) impurities. The channel supply layer 324 may have a material having a different polarization characteristic from that of the channel layer 323. For example, the channel supply layer 324 has a greater polarizability than that of the channel layer 323. The channel supply layer 324 may include a material having a greater energy band than that of the channel layer 323. For example, the channel supply layer 324 may be formed as a stacked structure in which a nitride including at least one of B, Al, Ga, and In, or a compound thereof are stacked. Two-dimensional electron gas (2DEG) may be generated in the channel layer 323 due to the channel supply layer 324. The 2DEG may be formed in a portion under an interface between the channel layer 323 and the channel supply layer 324, which corresponds to the channel layer 323. The 2DEG may be used as an n-type channel.

A source electrode S4, a drain electrode D4, and a gate electrode G4 may be disposed on the channel supply layer 324. The source electrode S4, the drain electrode D4, and the gate electrode G4 are separated from each other.

The electric field dispersion unit 325 may be formed on at least a part of the buffer layer 321. Here, the buffer layer 321 may include the entire nitride layer under the channel layer 323. The electric field dispersion unit 325 is disposed on a portion where the electric field is relatively concentrated in order to disperse the electric field, thereby improving the withstanding voltage characteristic. Therefore, the electric field dispersion unit 325 may be formed in a region of the buffer layer 321, which is under a space between the gate electrode G4 and the drain electrode D4 on which the electric field is relatively concentrated. The electric field dispersion unit 325 may be formed as a part of a thickness of the buffer layer 321. The electric field dispersion unit 325 may be formed of a high resistive material in order to improve the withstanding voltage characteristic. The electric field dispersion unit 325 may be formed of, for example, a dielectric material. The dielectric material may be at least one of SiO₂, SiON, SiN, AlN, and Al₂O₃. Otherwise, the electric field dispersion unit 325 may be formed by ion implantation. The ion implantation may be performed using a source material that forms a deep trap in the buffer layer 321. The ion implantation may be performed using at least one source material selected from the group consisting of, for example, N, O, He, H, F, C, and Fe.

On the other hand, at least one bonding metal layer may be disposed between the substrate 310 and the buffer layer 321. For example, the at least one bonding metal layer may include a first bonding metal layer 315 and a second bonding metal layer 317.

The electric field may be dispersed by the electric field dispersion unit 325, and thus, the withstanding voltage characteristic may be improved. In addition, the heat generated from the nitride-containing stack 320 may be dissipated through the substrate 310, and thereby preventing current characteristics from degrading. In addition, the power device 300 may be a high electric mobility transistor.

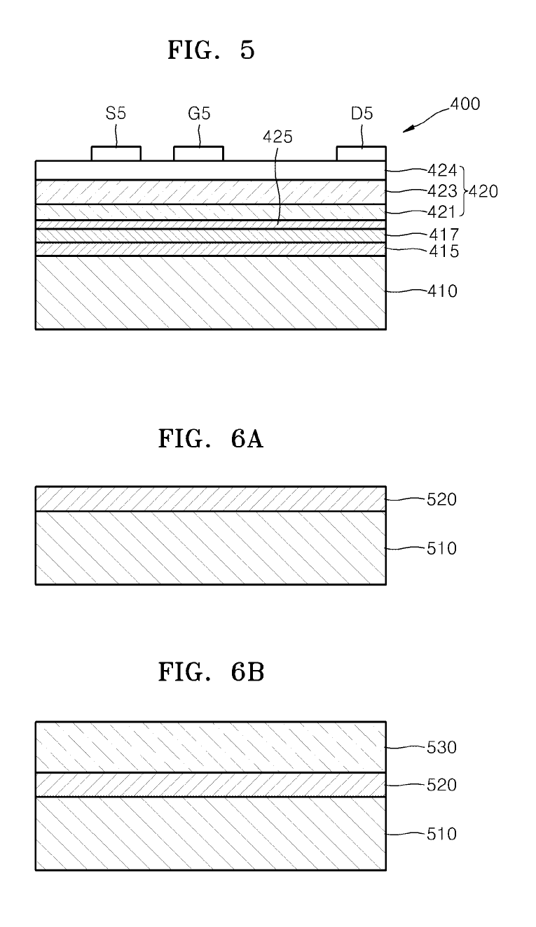

FIG. 5 is a cross-sectional view of a power device 400 according to a fifth example embodiment. Referring to FIG. 5, a nitride-containing stack 420 is disposed on a substrate 410, and an electric field dispersion unit 425 may be disposed between the substrate 410 and the nitride-containing stack 420. The electric field dispersion unit 425 may be formed by ion implantation and may be formed on an entire portion of a rear surface of the nitride-containing stack 420, which faces the substrate 410.

The nitride-containing stack 420 may include, for example, a buffer layer 421, a channel layer 423, and a channel supply layer 424. The buffer layer 421, the channel layer 423, and the channel supply layer 424 are substantially the same as those of FIG. 4 and thus detailed descriptions thereof are not provided here. A source electrode S5, a drain electrode D5, and a gate electrode G5 may be disposed on the channel supply layer 424. The source, drain, and gate electrodes S5, D5, and G5 are separated from each other.

The electric field dispersion unit 425 may be disposed on a lower surface of the buffer layer 421. The ion implantation may be performed using a source material that forms a deep trap in the buffer layer 421. The ion implantation may be performed using at least one source material selected from the group consisting of, for example, N, O, He, H, F, C, and Fe. If the electric field dispersion unit 325 is formed by a blank implantation process, dissipation of the heat from the nitride-containing stack 420 toward the substrate 410 is less affected even when the electric field dispersion unit 425 is formed on the entire lower surface of the buffer layer 421.

At least one bonding metal layer may be disposed between the substrate 410 and the electric field dispersion unit 425. The at least one bonding metal layer may include, for example, a first bonding metal layer 415 and a second bonding metal layer 417.

Next, a method of manufacturing a power device, according to an example embodiment, will be described.

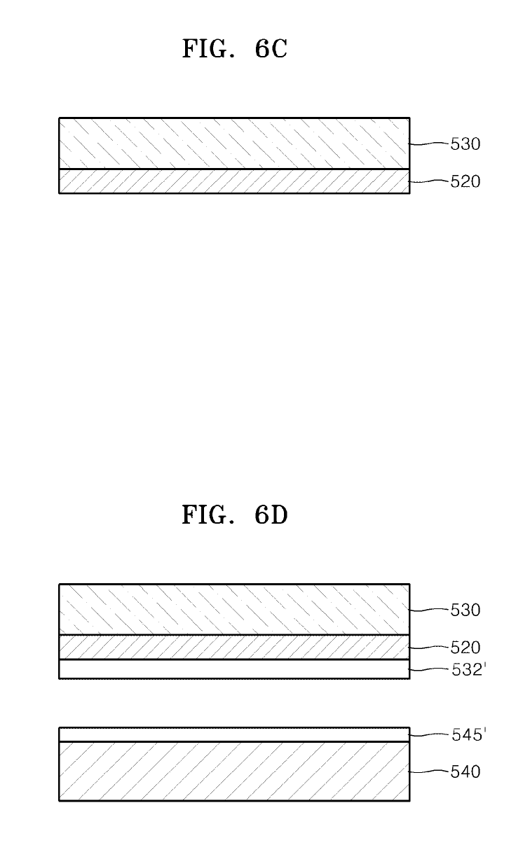

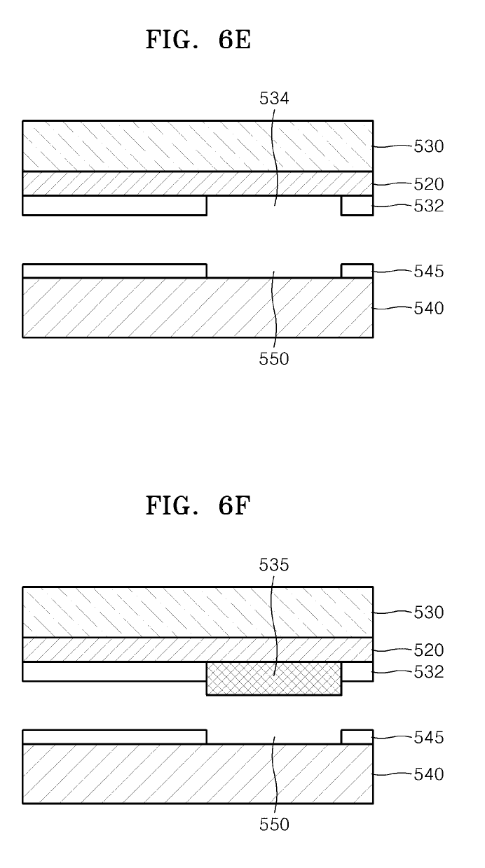

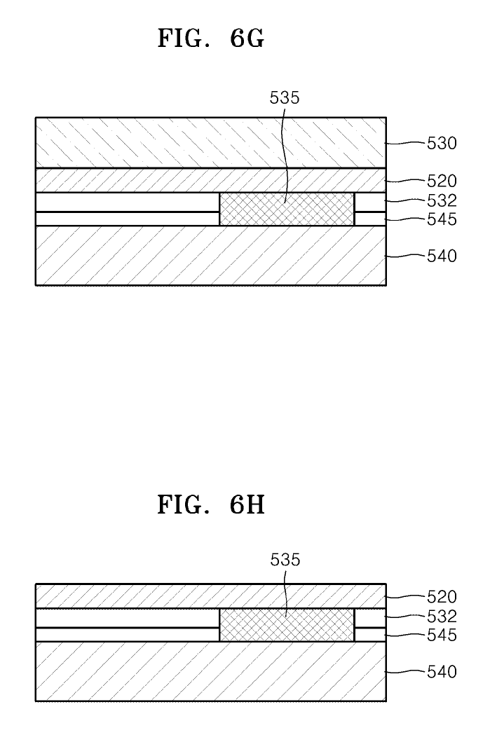

FIGS. 6A through 6H are cross-sectional views illustrating the method of manufacturing the power device, according to an embodiment of the present embodiment.

Referring to FIG. 6A, a nitride-containing stack 520 is grown on a first substrate 510. The nitride-containing stack 520 may include a plurality of nitride layers. The nitride-containing stack 520 may include, for example, a buffer layer, a channel layer, and a channel supply layer (refer to FIG. 4). The first substrate 510 may be, for example, a silicon substrate. Since the silicon substrate has a high thermal conductivity, the silicon substrate is not greatly bent under a high temperature for growing nitride thin films, and thus, large-size thin films may be grown. However, the silicon substrate is weak against an electric field, and a withstanding voltage characteristic may not be excellent. Therefore, the silicon substrate may be removed in order to improve the withstanding voltage characteristic. However, the first substrate 510 is not limited to the silicon substrate, and any substrate on which the nitride-containing stack may be grown may be used. Although not shown in the drawings, a source electrode, a gate electrode, and a drain electrode may be formed on the nitride-containing stack 520. Processes of forming the source, gate, and drain electrodes are well known in the art, and thus, detailed descriptions thereof are not provided here.

Referring to FIG. 6B, a carrier wafer 530 is deposited on the nitride-containing stack 520 before removing the first substrate 510. Then, as shown in FIG. 6C, the first substrate 510 is removed. Referring to FIG. 6D, at least a first bonding metal film 532′ may be disposed on a lower surface of the nitride-containing stack 520. In addition, at least a second bonding metal film 545′ may be disposed on a second substrate 540. The second substrate 540 may be formed of a material having high thermal conductivity. The second substrate 540 may be formed of Si, Al, Cu, SiC, GaN, AlN, or DBC. The first and second bonding metal films 532′ and 545′ may be formed of a material including at least one of Cu, Au, and Sn.

Referring to FIG. 6E, a first region 534 is patterned in the first bonding metal film to form the first bonding metal layer 532, and a second region 550 is patterned in the second bonding metal layer film to form to second bonding metal layer 545. The first and second regions 534 and 550 may be patterned by etching the first and second bonding metal films by using photoresist (not shown) and a mask (not shown). Since the etching process using the photoresist is well known in the art, detailed descriptions thereof are not provided here. Referring to FIG. 6F, an electric field dispersion unit 535 may be stacked in the first region 534. The electric field dispersion unit 535 may be formed of a dielectric material, and the dielectric material may include SiO₂, SiON, SiN, AlN, or Al₂O₃.

The electric field dispersion unit 535 may be stacked to be higher than the first region 534. For example, after stacking the electric field dispersion unit 535 in the first region 534, which formed by patterning by using the photoresist and the mask, the photoresist may be removed. The electric field dispersion unit 535 may have a size corresponding to the first and second regions 534 and 550, and the first and second bonding metal layers 532 and 545 may be wafer-bonded to each other (refer to FIG. 6G). After that, referring to FIG. 6H, the carrier wafer 530 is separated from the nitride-containing stack 520. According to the power device of the present embodiment, the electric field is dispersed by the electric field dispersion unit 535, thereby improving the withstanding voltage characteristic. In addition, the heat may be dissipated through the second substrate 540, and thus, degradation of current characteristics caused by the heat may be limited (and/or prevented).

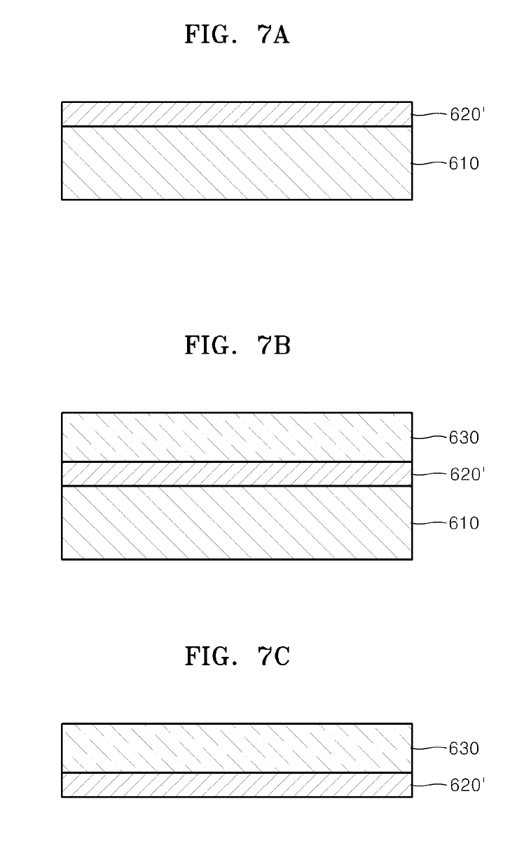

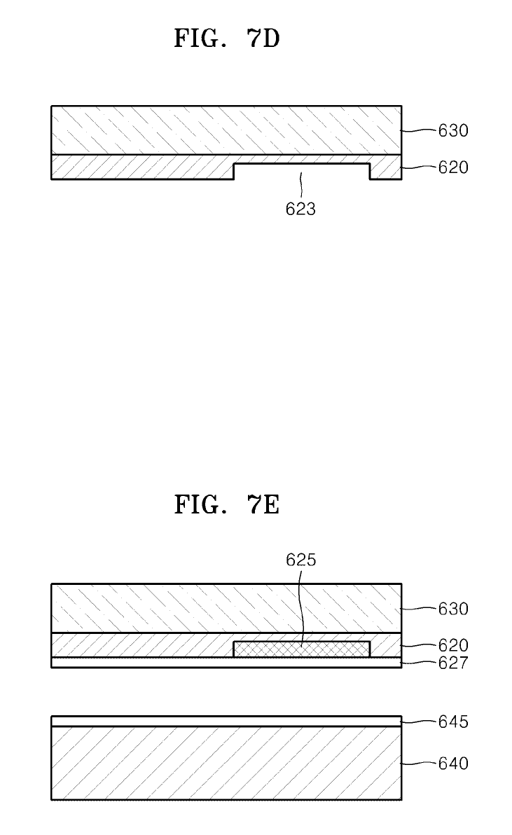

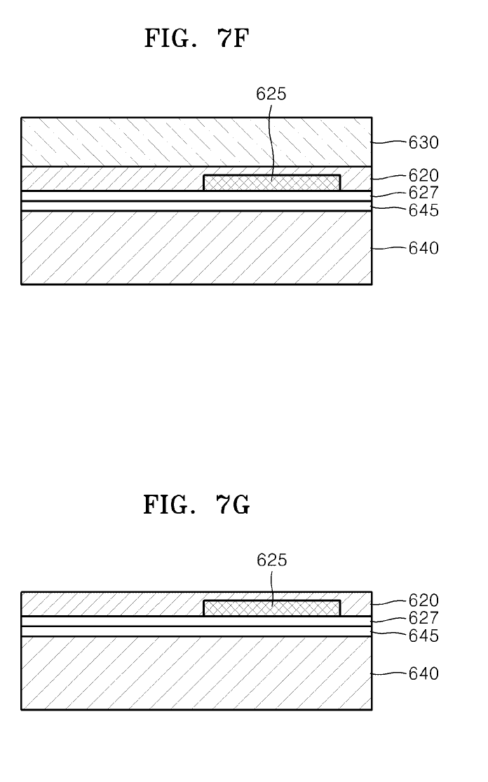

FIGS. 7A through 7G are cross-sectional views illustrating a method of manufacturing a power device, according to another example embodiment.

Referring to FIG. 7A, a nitride-containing stack 620 is grown on a first substrate 610. The nitride-containing stack 620′ may include a plurality of nitride layers. The first substrate 610 may be a silicon substrate, a silicon carbide substrate, or a GaN substrate.

Referring to FIG. 7B, a carrier wafer 630 is stacked on the nitride-containing stack 620′. After that, the first substrate 610 may be removed as shown in FIG. 7C. Referring to FIG. 7D, a region 623 may be patterned in a lower surface of the nitride-containing stack 620′ of FIG. 7C to form a nitride-containing stack 620. The region 623 may be patterned in a portion of a layer of the nitride-containing stack 620. The region 623 may be patterned by etching the nitride-containing stack 620 by using photoresist (not shown) and a mask (not shown). Referring to FIG. 7F, an electric field dispersion unit 625 may be stacked in the region 623. The electric field dispersion unit 625 may be formed of a dielectric material, which may include, for example, SiO₂, SiON, SiN, AlN, or Al₂O₃. At least a first bonding metal layer 627 may be disposed on lower surfaces of the nitride-containing stack 620 and the electric field dispersion unit 625. In addition, at least a second bonding metal layer 645 may be disposed on a second substrate 640. The second substrate 640 may be formed of a material having high thermal conductivity, for example, Si, Al, Cu, SiC, GaN, AlN, or DBC. The first and second bonding metal layers 627 and 645 may be formed of a material including at least one of Cu, Au, and Sn.

The nitride-containing stack 620 and the second substrate 640 may be wafer-bonded to each other by the first and second bonding metal layers 627 and 645 (refer to FIG. 7F). Then, referring to FIG. 7G, the carrier substrate 630 is separated from the nitride-containing stack 620.

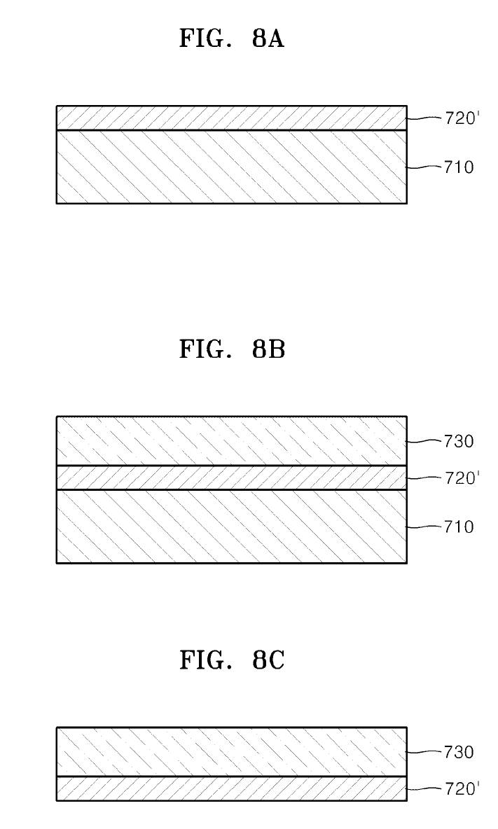

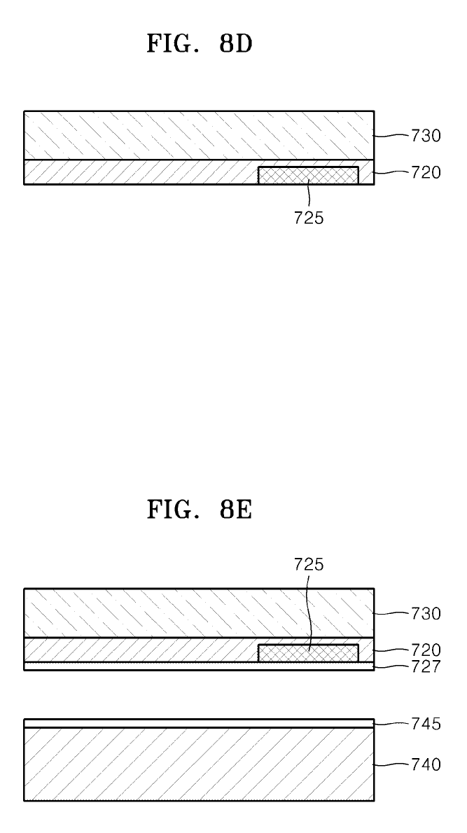

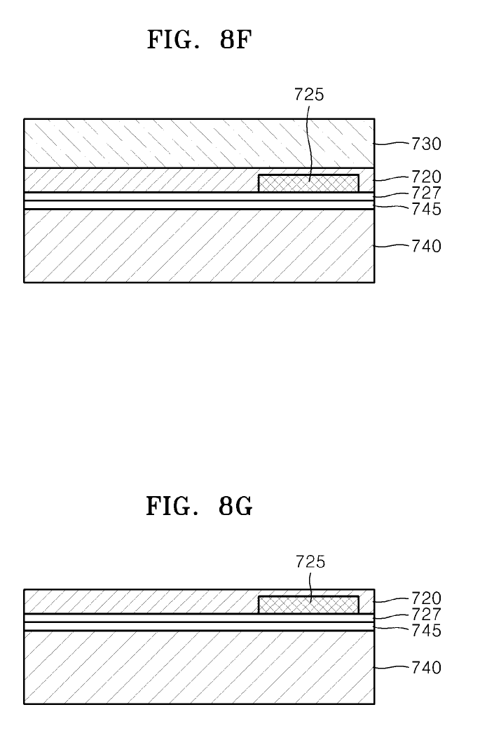

FIGS. 8A through 8G are cross-sectional views illustrating a method of manufacturing a power device, according to a different example embodiment.

Referring to FIG. 8A, a nitride-containing stack 720′ is grown on a first substrate 710. The nitride-containing stack 720 may include a plurality of nitride layers. The first substrate 710 may be a silicon substrate, a silicon carbide substrate, or a GaN substrate.

Referring to FIG. 8B, a carrier wafer 730 is stacked on the nitride-containing stack 720′. After that, as shown in FIG. 8C, the first substrate 710 may be removed. Referring to FIG. 8D, an electric field dispersion unit 725 may be formed on a part or an entire portion of a lower surface of the nitride-containing stack 720 by an ion implantation process. The ion implantation may be performed using a source material that forms a deep trap in a portion of a layer of the nitride-containing stack 720. The ion implantation may be performed using at least one source material selected from the group consisting of N, O, He, H, F, C, and Fe. In addition, the electric field dispersion unit 725 may be formed on the entire lower surface of the nitride-containing stack 720 by a blank ion implantation. For example, the nitride-containing stack 720 may include a buffer layer, a channel layer, and a channel supply layer, and the electric field dispersion unit 725 may be formed on a part of or an entire lower surface of the buffer layer by the ion implantation process.

Referring to FIG. 8E, at least a first bonding metal layer 727 may be disposed on lower surfaces of the nitride-containing stack 720 and the electric field dispersion unit 725. In addition, at least a second bonding metal layer 745 may be disposed on the second substrate 740. The second substrate 740 may be formed of a material having high thermal conductivity, for example, Si, Al, Cu, SiC, GaN, AlN, or DBC. The first and second bonding metal layers 727 and 745 may be formed of a material including at least one of Cu, Au, and Sn.

Referring to FIG. 8F, the nitride-containing stack 720 and the second substrate 740 may be wafer-bonded to each other by the first and second bonding metal layers 727 and 745. After that, referring to FIG. 8G, the carrier substrate 730 may be separated from the nitride-containing stack 720.

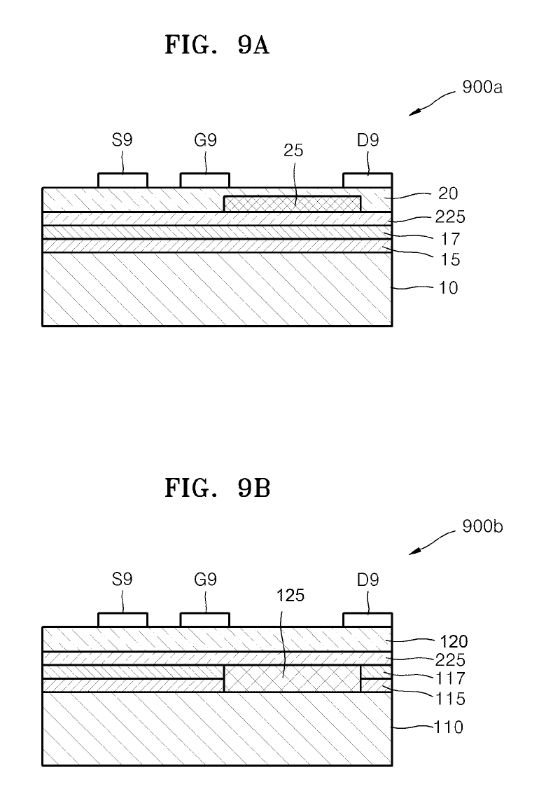

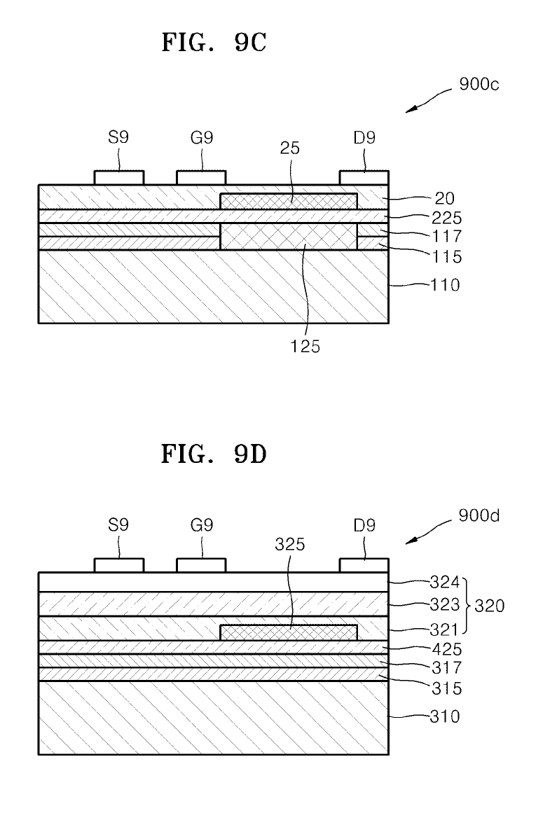

FIGS. 9A to 9D are schematic cross-sectional views of power devices according to some example embodiments. Only the differences between the power devices illustrated in FIGS. 9A to 9D and the power devices in FIGS. 1 to 5 will described.

Referring to FIG. 9A, a power device 900a according to an example embodiment may have the same structure as the power device 1 illustrated in FIG. 1, except the power device 900a may further include another electric field dispersion unit 225 between the second metal bonding layer 17 and a partial rear surface or an entire rear surface of the nitride-containing stack 20. The other electric field dispersion unit 225 in the power device 900a may have the same structure as the electric field dispersion unit 225 described above with reference to FIG. 3.

Referring to FIG. 9B, a power device 900b according to an example embodiment may have the same structure as the power device 100 illustrated in FIG. 2, except the power device 900b may further include another electric field dispersion unit 225 between the second metal bonding layer 17 and a partial rear surface or an entire rear surface of the nitride-containing stack 120. The other electric field dispersion unit 225 in the power device 900b may have the same structure as the electric field dispersion unit 225 described above with reference to FIG. 3.

Referring to FIG. 9C, a power device 900c according to an example embodiment may have the same structure as the power device 900b illustrated in FIG. 9C, except the power device 900c may include a nitride-containing stack 20 having an additional electric field dispersion unit 25 instead of the nitride-containing stack 120 described above with reference to FIG. 9B.

Referring to FIG. 9D, a power device 900d according to an example embodiment may have the same structure as the power device 300 illustrated in FIG. 4, except the power device 900d may further include an electric field dispersion unit 425 between the a partial rear surface or an entire rear surface of the buffer layer 321 and the second metal bonding layer 317.

According to an example embodiment, a power device includes a nitride-containing stack and a second substrate blocked from each other by an electric field dispersion unit, thereby maintaining a high breakdown characteristic. In addition, the heat generated from the device may be dissipated through the second substrate that has high thermal conductivity, and thus, the degradation of device characteristics caused by the self-heating may be limited (and/or prevented).

Descriptions of features or aspects within each embodiment should typically be considered as available for other similar features or aspects in other embodiments. While some example embodiments have been particularly shown and described, it will be understood by one of ordinary skill in the art that variations in form and detail may be made therein without departing from the spirit and scope of the claims.

What is claimed is:

1. A power device comprising:
a substrate;
a nitride-containing stack on the substrate;
a source electrode, a drain electrode, and a gate electrode on the nitride-containing stack,
the nitride-containing stack including a first region that is configured to generate a larger electric field than that of a second region of the nitride-containing stack; and
an electric field dispersion unit between the substrate and the first region of the nitride-containing stack.

2. The power device of claim 1, wherein the electric field dispersion unit includes a dielectric material.

3. The power device of claim 2, wherein
the electric field dispersion unit is between the substrate and a part of a bottom surface of the nitride-containing stack, and
the electric dispersion unit is not under the source electrode.

4. The power device of claim 2, wherein the dielectric material includes at least one of SiO₂, SiON, SiN, AlN, and Al₂O₃.

5. The power device of claim 1, wherein
the electric field dispersion unit is between the substrate and an entire bottom surface of the nitride-containing stack, and
the electric field dispersion unit is formed by ion implantation, and
the ion implantation forms a deep trap in the bottom surface of the nitride-containing stack.

6. The power device of claim 5, wherein the ion implantation is performed using a source material including at least one of N, O, He, H, F, C, and Fe.

7. The power device of claim 5, wherein the ion implantation is performed to a depth of 10 nm or greater.

8. The power device of claim 1, wherein a part of the electric field dispersion unit is under a part of the drain electrode.

9. The power device of claim 1, wherein
the electric field dispersion unit is under a part of an upper surface of the nitride-containing stack, and
the part of the upper surface of the nitride-containing stack is between the gate electrode and the drain electrode.

10. The power device of claim 1, wherein the power device is a high electron mobility transistor.

11. The power device of claim 1, further comprising:
at least one bonding metal layer between the nitride-containing stack and the substrate.

12. The power device of claim 11, wherein the at least one bonding metal layer contains at least one of Cu, Au, and Sn.

13. The power device of claim 1, wherein the substrate includes one of Si, Al, Cu, SiC, GaN, AlN, and a direct bonded copper (DBC).

14. A power device comprising:
a substrate;
a buffer layer on the substrate;
a GaN channel layer on the buffer layer;
a channel supply layer on the channel layer;
a source electrode, a drain electrode, and a gate electrode on the channel supply layer; and
an electric field dispersion unit on one of a portion region the buffer layer and at least a portion region of a bottom surface of the buffer layer,
the electric field dispersion unit being configured to disperse an electric field.

15. The power device of claim 14, wherein at least one of the buffer layer and the channel supply layer is a nitride material that includes at least one of B, Al, Ga, In, and combinations thereof.

16. The power device of claim 14, wherein the electric field dispersion unit includes a dielectric material.

17. The power device of claim 16, wherein the dielectric material includes at least one of SiO₂, SiON, SiN, AlN, and Al₂O₃.

18. The power device of claim 14, wherein
the electric field dispersion unit is formed by ion implantation, and
the ion implantation forms a deep trap in the buffer layer.

19. The power device of claim 18, wherein
the ion implantation is performed using at least one of N, O, He, H, F, C, and Fe as a source material.

20. The power device of claim 14, wherein a part of the electric field dispersion unit is under a part of the drain electrode.

21. The power device of claim 14, wherein
the electric field dispersion unit is under a part of an upper surface of the nitride-containing stack, and
the part of the upper surface of the nitride-containing stack is between the gate electrode and the drain electrode.

22. The power device of claim 14, further comprising:
at least one bonding metal layer between the buffer layer and the substrate.

23. The power device of claim 22, wherein the at least one bonding metal layer comprises a material including at least one of Cu, Au, and Sn.

24. The power device of claim 14, wherein the substrate includes one of Si, Al, Cu, SiC, GaN, AlN, and a direct bonded copper (DBC).

25. A method of manufacturing a power device the method comprising:
stacking a buffer layer on a first substrate;
stacking at least one nitride semiconductor layer on the buffer layer;
forming a source electrode, a gate electrode and a drain electrode on the at least one nitride semiconductor layer;
removing the first substrate;
forming an electric field dispersion unit on at least a region of a bottom surface of the buffer layer; and
forming a second substrate on the buffer layer and the electric field dispersion unit

26. The method of claim 25, wherein the forming of the electric field dispersion unit comprises:
patterning a part of the buffer layer: and
stacking a dielectric material in the patterned portion.

27. The method of claim 26, wherein the material includes at least one of SiO₂, SiN, AlN, and Al₂O₃.

28. The method of claim 25, wherein the forming of the electric field dispersion unit comprises:
forming at least one bonding metal layer on the buffer layer;
patterning a part of the bonding metal layer;
stacking a dielectric material in the patterned part of the at least one bonding metal layer;
patterning the second substrate; and
bonding the second substrate to the at least one bonding metal layer so that the dielectric material and the patterned part of the second substrate are bonded to each other.

29. The method of claim 25, wherein the forming of the electric field dispersion unit comprises performing an ion implantation on a part or an entire part of the buffer layer.

30. The method of claim 29, wherein the ion implantation is performed using a source including at least one of N, O, He, H, F, C, and Fe.

31. The method of claim 25, wherein the electric field dispersion unit is formed under a part of the drain electrode.

32. The method of claim 25, wherein the electric field dispersion unit is under lower portions of the gate electrode and the drain electrode.

33. The method of claim 25, wherein the second substrate is one of Si, Al, Cu, SiC, GaN, AlN, and a direct bonded copper (DBC).
